(19) United States
(12) Patent Application Publication
(10) Pub. No.: US 2013/0118567 A1
(43) Pub. Date: May 16, 2013

(54) TANDEM SOLAR CELL USING AMORPHOUS SILICON SOLAR CELL AND ORGANIC SOLAR CELL

(71) Applicants: Kyungkon Kim, Seoul (KR); Seung Hee Han, Seoul (KR); Hong Gon Kim, Seoul (KR); Min Jae Ko, Chungcheongnam-do (KR); Doh Kwon Lee, Seoul (KR); Tae Hee Kim, Seoul (KR)

(72) Inventors: Kyungkon Kim, Seoul (KR); Seung Hee Han, Seoul (KR); Hong Gon Kim, Seoul (KR); Min Jae Ko, Chungcheongnam-do (KR); Doh Kwon Lee, Seoul (KR); Tae Hee Kim, Seoul (KR)

(73) Assignee: KOREA INSTITUTE OF SCIENCE AND TECHNOLOGY, Seoul (KR)

(21) Appl. No.: 13/810,553

(22) PCT Filed: Aug. 5, 2011
(86) PCT No.: PCT/KR11/05742

§ 371 Date: Jan. 16, 2013

(30) Foreign Application Priority Data
Aug. 6, 2010 (KR) 10-2010-0075911

(51) Int. Cl. H01L 31/078

(52) U.S. Cl. CPC H01L 31/078
USPC 136/255

(57) ABSTRACT

A tandem solar cell comprising an amorphous silicon solar cell including a photoactive layer made of amorphous silicon; and an organic solar cell including a photoactive layer made of an organic material, which are stacked and electrically connected in series can absorb a wider wavelength range of light, exhibit improved open-circuit voltage (V_{oc}) performance, and be mass produced in a simple manner at low cost.

### FIELD OF THE INVENTION

The present invention relates to a tandem solar cell using two kinds of solar cells having different band gaps, namely, an amorphous silicon solar cell and an organic solar cell, which can absorb a wider wavelength range of light and exhibit improved open-circuit voltage performance.

### BACKGROUND OF THE INVENTION

Since solar cells having an efficiency of 4.5% were developed in Bell Labs, USA, in 1954, the development of silicon solar cells took place in earnest. Subsequent continuous and thorough research resulted in silicon solar cells having a maximum efficiency of 24.7% in 1999. For actual commercialization, production cost and productivity are regarded as important, as well as the efficiency of the silicon solar cell, and thus amorphous thin-film silicon solar cells which are advantageous in terms of low material and process costs and a maximum efficiency of about 10% are receiving attention.

Typically, silicon solar cells are classified into a substrate type and a thin-film type, depending on the form of material. The substrate type silicon solar cell is further divided into, depending on the material of the light absorbing layer, a single-crystalline silicon solar cell and a poly-crystalline silicon solar cell. The thin-film type silicon solar cell is also divided into an amorphous silicon (a-Si:H) solar cell and a micro-crystalline silicon (c-Si:H) solar cell, depending on the material of the light absorbing layer. The crystalline silicon substrate includes a silicon wafer and thus increases the production cost and undergoes complicated processing, undesirably resulting in decreased productivity. On the other hand, the amorphous silicon solar cell has low material cost and is adapted for continuous mass production processes, thus making it possible to achieve the actual commercialization thereof. Hence, thorough research thereinto is ongoing in many enterprises, labs and universities.

The structure of the silicon solar cell is typically provided in the form of a diode having a p-n junction. However, because the amorphous silicon thin film has a carrier diffusion length much lower than that of the crystalline silicon substrate, it has undesirably low collection efficiency of electron-hole pairs formed by light when manufactured in the form of a p-n structure. Thus, the amorphous silicon solar cell is manufactured in the form of a p-i-n structure in which a non-doped intrinsic (i-type) amorphous silicon light absorbing layer is interposed between the p-type amorphous silicon layer and the n-type amorphous silicon layer. The typical structure of the amorphous silicon solar cell is shown in FIG. 1. As shown in FIG. 1, the amorphous silicon solar cell includes a transparent electrode layer 20, a p-type amorphous silicon layer 30, an i-type amorphous silicon layer 40, an n-type amorphous silicon layer, and a metal electrode layer 60, which are sequentially formed on a glass substrate 10.

On the other hand, the organic solar cell uses an organic material as a light absorbing layer, and thus has a much lower cost of materials compared to an inorganic material such as silicon, and has a very simple fabrication process thereby remarkably reducing the production cost. The organic solar cell is formed of organic materials having electron donor and acceptor properties. The operating principle of this cell is that when light energy is incident on a photoactive layer made of an organic material, electrons become excited, and the excited electrons and the holes left behind after release of the electrons are electrostatically weakly bound to each other to thus form excitons which are electron-hole pairs. In order for the excitons produced by solar light to actually generate photocurrent, the electron-hole pairs are dissociated into electrons and holes, respectively. As such, the electrons should move to the cathode, whereas the holes should move to the anode. With the technical advancement of polymer solar cells, energy conversion efficiency is recently increasing. The polymer system used as a representative example of the organic solar cell is composed mainly of a mixture solution comprising a conjugated polymer such as poly(3-hexylthiophene) (P3HT) and [6,6]-phenyl-Cₓ-butyric acid methyl ester (PCₓBM) as a main material. The typical structure of organic solar cell is shown in FIG. 2. As shown in FIG. 2, the organic solar cell is typically configured such that a transparent electrode layer 20, a hole transporting layer 70, a light absorbing layer 80 and a metal electrode layer 60 are sequentially formed on a glass substrate 10.

In addition, tandem solar cells were reported to be manufactured by stacking two or more kinds of single solar cells and electrically connecting them in series. When the tandem solar cell is manufactured from two or more kinds of solar cells having different band gaps, solar light of a wide wavelength range can be utilized, and also two or more kinds of solar cells are connected in series and thus open-circuit voltage (V_{oc}) can increase, advantageously resulting in high efficiency. The V_{oc} of the tandem solar cell corresponds to the sum of values of respective single solar cells, and short-circuit current density (J_{sc}) of the tandem solar cell is determined by the smaller value among J_{sc} values of respective single solar cells. As such, a single solar cell having smaller J_{sc} is defined as a limiting cell. When briefly describing the operating principle of the tandem solar cell, solar light is absorbed by respective light absorbing layers so that electrons and holes are produced, in which photo-electrons produced in the i-type amorphous silicon layer are transferred to the n-type amorphous silicon layer by an electric field formed in the cell, and thus recombine with the holes which are moved to the hole transporting layer from the organic photoactive layer. Furthermore, the holes produced in the i-type amorphous silicon layer are transferred to the p-type amorphous silicon layer and are then collected by the transparent electrode, and the photo-electrons produced in the organic photoactive layer are collected by the metal electrode, thereby generating current along the circuit.

The amorphous silicon solar cell has a band gap of about 1.7˜1.9 eV, which is comparatively higher than that of the crystalline silicon solar cell and is thus disadvantageous because it cannot absorb solar light of long wavelengths. In order to solve this problem, there has been research into the development of a tandem solar cell comprising the amorphous silicon solar cell and the micro-crystalline silicon solar cell which are stacked so that solar light of a wide wavelength range is absorbed and the cell efficiency is increased. However, the micro-crystalline silicon has a coefficient of light absorption smaller than that of the amorphous silicon, and thus should be formed thick in order to sufficiently absorb light, and also a crystallization process using heat treatment should be added. For this reason, the tandem solar cell having the above structure is problematic in terms of decreased productivity and increased production cost.

### SUMMARY OF THE INVENTION

It is, therefore, an object of the present invention to provide a tandem solar cell, which can absorb a wider wavelength range of light, exhibit improved open-circuit voltage (V_{oc}) performance, and be mass produced in a simple manner at low cost.

In accordance with one aspect of the present invention, there is provided a tandem solar cell comprising an amorphous silicon solar cell including a photoactive layer made of amorphous silicon; and an organic solar cell including a photoactive layer made of an organic material, which are stacked and electrically connected in series.

### BRIEF DESCRIPTION OF THE DRAWINGS

The above and other objects and features of the present invention will become apparent from the following description of preferred embodiments given in conjunction with the accompanying drawings, in which:

FIG. 1 schematically illustrates a typical structure of an amorphous silicon solar cell;

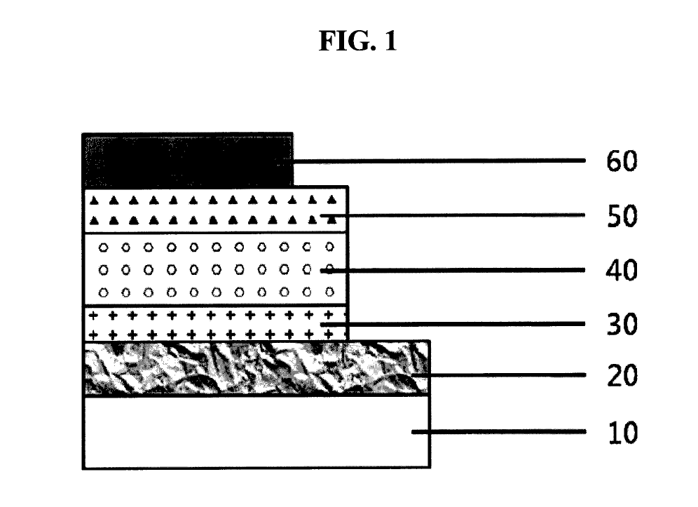

FIG. 2 schematically depicts a typical structure of an organic solar cell;

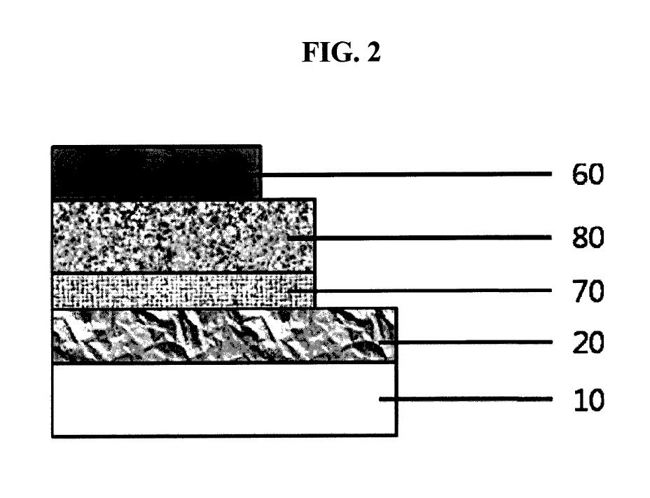

FIG. 3 schematically shows a structure of a tandem solar cell comprising an amorphous silicon solar cell and an organic solar cell which are stacked, according to a preferred embodiment of the present invention;

FIG. 4 describes current-voltage graphs of the solar cells of Examples 1 and 2 and Comparative Examples 1 and 2, measured under conditions of AM 1.5 light irradiation (in Comparative Example 2, the current-voltage properties were measured by applying light passed through an amorphous silicon sample under AM 1.5 light irradiation conditions); and

FIGS. 5A and 5B illustrate measurement results of incident photon-current conversion efficiency (IPCE) for the solar cells of Example 2 and Comparative Examples 1 and 2.

### DESCRIPTION ON MARKS IN FIGURES

10: glass substrate

20: transparent electrode layer

30: p-type amorphous silicon layer

40: i-type amorphous silicon layer

50: n-type amorphous silicon layer

60: metal electrode layer

70: hole transporting layer

80: organic photoactive layer

90: electron transporting layer

### DETAILED DESCRIPTION OF THE PREFERRED EMBODIMENTS

According to the present invention, a tandem solar cell comprises an amorphous silicon solar cell having an amorphous silicon photoactive layer and an organic solar cell having an organic photoactive layer which are stacked and electrically connected in series. The amorphous silicon solar cell absorbs a short wavelength region of light and the organic solar cell absorbs a long wavelength region of light, and thus the tandem solar cell according to the present invention can absorb light over a wider range of wavelengths.

According to a preferred embodiment of the present invention, the tandem solar cell has the structure that comprises a glass substrate, a transparent electrode layer, a p-type amorphous silicon layer, an i-type amorphous silicon layer, an n-type amorphous silicon layer, a hole transporting layer, an organic photoactive layer, and a metal electrode layer which are sequentially stacked.

Also, the tandem solar cell according to the present invention may further include an electron transporting layer placed between the organic photoactive layer and the metal electrode layer, and a metal recombination layer placed between the n-type amorphous silicon layer and the hole transporting layer.

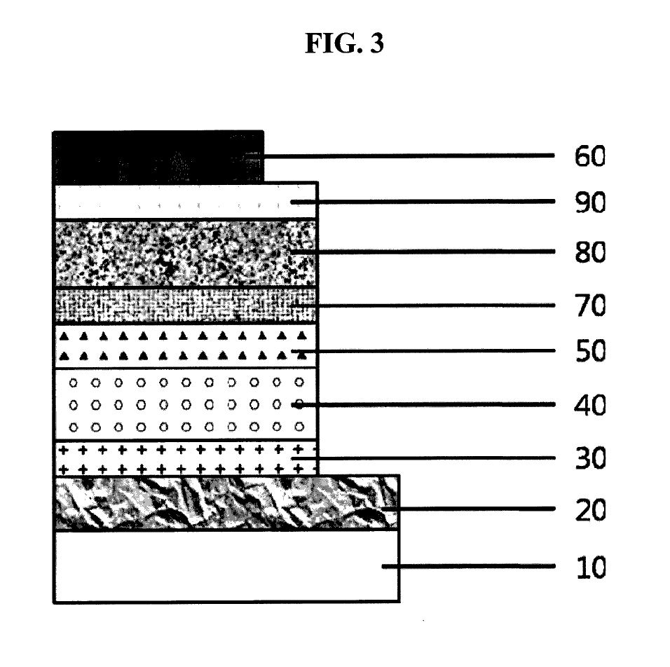

The structure of the tandem solar cell according to the preferred embodiment of the present invention is shown in FIG. 3. As shown in FIG. 3, the tandem solar cell is configured such that the glass substrate 10, the transparent electrode layer 20, the p-type amorphous silicon layer 30, the i-type amorphous silicon layer 40, the n-type amorphous silicon layer 50, the hole transporting layer 70, the organic photoactive layer 80, the electron transporting layer 90 and the metal electrode layer 60 are sequentially stacked.

The layers of the solar cell may be formed at predetermined thicknesses using typical materials by means of typical methods.

For example, the hole transporting layer or the electron transporting layer may be made of one or more materials selected from the group consisting of titanium (Ti) oxide, zirconium (Zr) oxide, strontium (Sr) oxide, zinc (Zn) oxide, indium (In) oxide, lanthanum (La) oxide, vanadium (V) oxide, molybdenum (Mo) oxide, tungsten (W) oxide, tin (Sn) oxide, niobium (Nb) oxide, magnesium (Mg) oxide, aluminum (Al) oxide, yttrium (Y) oxide, scandium (Sc) oxide, samarium (Sm) oxide, gallium (Ga) oxide, strontium-titanium (Sr—Ti) oxide, lithium fluoride (LiF), poly(3,4-ethylenedioxythiophene):poly(styrenesulfonate) (PEDOT:PSS), polyaniline, and polypyrrole.

The metal recombination layer may be made of one or more materials selected from the group consisting of gold (Au), silver (Ag), nickel (Ni), aluminum (Al), titanium (Ti), platinum (Pt), palladium (Pd) and copper (Cu).

In order to manufacture the tandem solar cell according to the present invention, the glass substrate is first prepared. An indium-tin oxide (ITO) layer which is the transparent electrode layer may be formed on the glass substrate using sputtering. Besides ITO, an example of a transparent conductive oxide (TCO), a fluorine-doped tin oxide (FTO) may be used in formation of the transparent electrode layer. Because solar light is incident on the glass substrate, the glass substrate and the transparent electrode layer preferably should be as transparent as possible. The p-type amorphous silicon layer may be formed on the ITO electrode layer using plasma-enhanced chemical vapor deposition (PECVD). The i-type amorphous silicon layer may be formed on the p-type amorphous silicon layer using PECVD, and subsequently the n-type amorphous silicon layer, on the i-type amorphous silicon layer using PECVD. The amorphous silicon may be hydrogenated amorphous silicon as represented by a-Si:H. The i-type (intrinsic) amorphous silicon indicates a state free of added impurities, and the p-type (positive) and n-type (negative) indicate a doped state in which an impurity has been added to amorphous silicon. In order to form the p-type amorphous silicon, a trivalent element such as boron and potassium may be added, and in order to form the n-type amorphous silicon, a pentavalent element such as phosphorus, arsenic and antimony may be added. The hole transporting layer may be formed on the n-type amorphous silicon layer using thermal evaporation or spin coating. Subsequently, the organic photoactive layer may be formed on the hole transporting layer using spin coating, and then the electron transporting layer, on the organic photoactive layer using spin coating. Finally, the metal electrode may be formed on the electron transporting layer using thermal evaporation, thereby completing the tandem solar cell.

Also, if necessary, when the above procedure is repeated, it is possible to manufacture multilayered solar cells having three, four or more layers, in addition to the two-layered structure.

With the goal of overcoming the limitation of the amorphous silicon solar cell which is advantageous in terms of material cost and process cost but does not utilize solar light of long wavelengths, the inventive tandem solar cell comprises the organic solar cell which can be simply manufactured at low material cost and absorb light of long wavelengths in a stacked form together with the amorphous silicon solar cell, thereby be able to absorb a wider wavelength range of light and to exhibit improved V_{oc} performance. Also, the tandem solar cell according to the present invention can be mass produced at low cost due to its convenient manufacture.

The following examples may provide a better understanding of the present invention and provide an illustration thereof, but are not to be construed as limiting the present invention.

### EXAMPLE 1

### Tandem Solar Cell Using PEDOT:PSS as Hole Transporting Layer

A glass substrate having a transparent electrode layer composed of ITO formed at a thickness of 200 nm thereon was prepared. The glass substrate having the ITO layer was cleaned by washing it with ultra-sonication using isopropylalcohol (IPA) for 10 min, acetone for 10 min, and then IPA for 10 min, drying it at 80° C. in a vacuum for 10 min, and then ozone treating it for 20 min.

Subsequently, a p-type amorphous silicon layer having a thickness of 5 nm, an i-type amorphous silicon layer having a thickness of 120 nm and an n-type amorphous silicon layer having a thickness of 25 nm were sequentially formed on the ITO transparent electrode layer using PECVD.

Subsequently, a mixture solution comprising aqueous PEDOT:PSS (CLEVIOS, AI4083) and methanol at a volume ratio of 1:1 was subjected to spin coating at 4000 rpm for 40 sec on the n-type amorphous silicon layer, thus forming a 30 nm-thick hole transporting layer. In order to evaporate excess solvent from the PEDOT:PSS layer, this layer was dried at 110° C. for 10 min, after which a 1:4 weight ratio solution of poly[2,6-(4,4-bis-(2-ethylhexyl)-4H-cyclopenta[2,1-b;3,4-b′]-dithiophene)-alt-4,7-(2,1,3-benzothiadiazole)] (PCPDTBT) and [6,6]-phenyl-C₇₁-butyric acid methyl ester (PC₇₁BM, Nano-C) dissolved in chlorobenzene (Aldrich) was subjected to spin coating at 2000 rpm, thus forming an organic photoactive layer at a thickness of about 70 nm. Subsequently, a solution of 0.5 wt % titanium oxide (TiO₂) nanoparticles dispersed in 1-butanol (Aldrich) was subjected to spin coating at 800 rpm on the organic photoactive layer, thus forming an electron transporting layer at a thickness of about 20 nm. Subsequently, an Al metal electrode layer was deposited on the electron transporting layer at a 100 nm thickness in a high vacuum of 10⁻⁶ torr (1 torr=133.3 Pa) or less using a thermal evaporator (DaeDong Hightech Corp.), thereby manufacturing a tandem solar cell. Al was selectively deposited using a stainless steel shadow mask, and the active area of the solar cell was defined by the overlapping area of the ITO electrode and the Al electrode stacked together.

### EXAMPLE 2

### Tandem Solar Cell Using MoO₃ as Hole Transporting Layer

A tandem solar cell was manufactured in the same manner as in Example 1, with the exception that MoO₃ was used instead of PEDOT:PSS as the material of the hole transporting layer formed on the n-type amorphous silicon layer. The MoO₃ hole transporting layer was formed at a thickness of about 3.5 nm using thermal evaporation.

### COMPARATIVE EXAMPLE 1

### Single Amorphous Silicon Solar Cell

In order to compare the degree of increase in V_{oc} of the tandem solar cell connected in series according to the present invention, a conventional amorphous silicon solar cell having a single photoactive layer structure was manufactured. According to the manufacturing process as in Example 1, a p-type amorphous silicon layer, an i-type amorphous silicon layer and an n-type amorphous silicon layer were sequentially created on the ITO transparent electrode layer using PECVD. Subsequently, an Al metal electrode layer was formed at a thickness of 100 nm on the n-type amorphous silicon layer using thermal evaporation, thereby manufacturing the single amorphous silicon solar cell.

### COMPARATIVE EXAMPLE 2

### Single Organic Solar Cell

In order to compare the efficiency of the tandem solar cell connected in series according to the present invention, a conventional organic solar cell having a single photoactive layer structure was manufactured. According to the manufacturing process, a MoO₃ hole transporting layer was formed at a thickness of 3.5 nm on the ITO transparent electrode layer using thermal evaporation, and then as in Example 1, a mixture solution comprising PCPDTBT and PC₇₁BM at a weight ratio of 1:4 was subjected to spin coating at a thickness of 70 nm, thus forming an organic photoactive layer. Subsequently, 0.5 wt % TiO₂ nanoparticles dissolved in butanol were subjected to spin coating, thus forming an electron transporting layer at a thickness of about 20 nm, and an Al metal electrode layer was deposited thereon at a thickness of 100 nm using thermal evaporation, thereby manufacturing the single organic solar cell. Upon measurement of the efficiency, only the light remaining after absorbed by a single amorphous silicon sample having no metal electrode layer was incident on the single organic solar cell in order to measure the efficiency under the same conditions as the structure of an actual tandem solar cell.

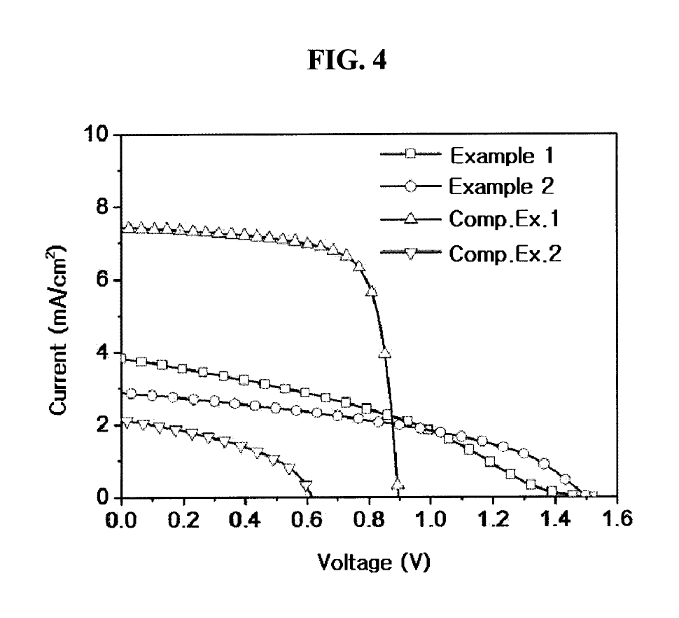

The properties of the solar cells of Examples 1 and 2 and Comparative Examples 1 and 2 were measured. The results are shown in FIG. 4 and Table 1 below. The conversion efficiency was measured using a 1.5 AM 100 mW/cm² solar simulator (Xe lamp [2500 W], AM1.5 filter, and Keithley model2400).

In the graph of FIG. 4, the current density is the Y axis of the conversion efficiency curve, and the voltage is the X axis of the conversion efficiency curve, and J_{sc} and V_{oc} are the intercept values of respective axes.

In FIG. 4 and Table 1, when the current density and the voltage at a maximum power point (MPP) at which the power (obtained by multiplying the current density by the voltage) is maximized are respectively Jₘₐₓ and Vₘₐₓ, a fill factor (FF) becomes calculated as a percentage of the ratio of (Jₘₐₓ×Vₘₐₓ) to (J_{sc}×V_{oc}).

| | J_{sc} (mAcm⁻²) | V_{oc} (mV) | FF (%) | Efficiency (%) |
|---|---|---|---|---|
| Ex. 1 | 3.83 | 1491.2 | 33.99 | 1.94 |
| Ex. 2 | 2.88 | 1501.4 | 42.19 | 1.83 |
| C. Ex. 1 | 7.43 | 895.2 | 73.15 | 4.87 |
| C. Ex. 2 | 2.14 | 616.1 | 42.09 | 0.55 |

As is apparent from FIG. 4 and Table 1, the V_{oc} of the tandem solar cells of Examples 1 and 2 approximates the sum of V_{oc} values of respective single solar cells of Comparative Examples 1 and 2. This means that respective single solar cells are electrically connected in series to successfully embody the tandem solar cell. In particular, the tandem solar cell of Example 2 has the V_{oc} and FF higher than those of the tandem solar cell of Example 1. This is considered to be because the use of PEDOT:PSS as the hole transporting layer obstructs effective charge transport and recombination on the interface between the n-type amorphous silicon layer and the hole transporting layer, due to hydrophobicity of the amorphous silicon layer and hydrophilic conductivity of the hole transporting layer, which causes increase of an internal resistance. When the tandem solar cell is manufactured using the amorphous silicon solar cell and the organic solar cell in this way, charge transport on the interface is regarded as very important. Metal oxides such as MoO₃ rather than PEDOT:PSS has higher affinity to the inorganic amorphous silicon solar cell, due to hydrophobicity of both of the amorphous silicon layer and the metal oxide hole transporting layer. Thus, when the hole transporting layer of a metal oxide including MoO₃ is used, the FF of the tandem solar cell which is almost the same as that of the limiting cell can be obtained. Further, the formation of the metal oxide hole transporting layer including the MoO₃ layer which is neutral is free of risk of etching the amorphous silicon layer previously formed, unlike the PEDOT:PSS hole transporting layer which is strongly acidic (pH 1).

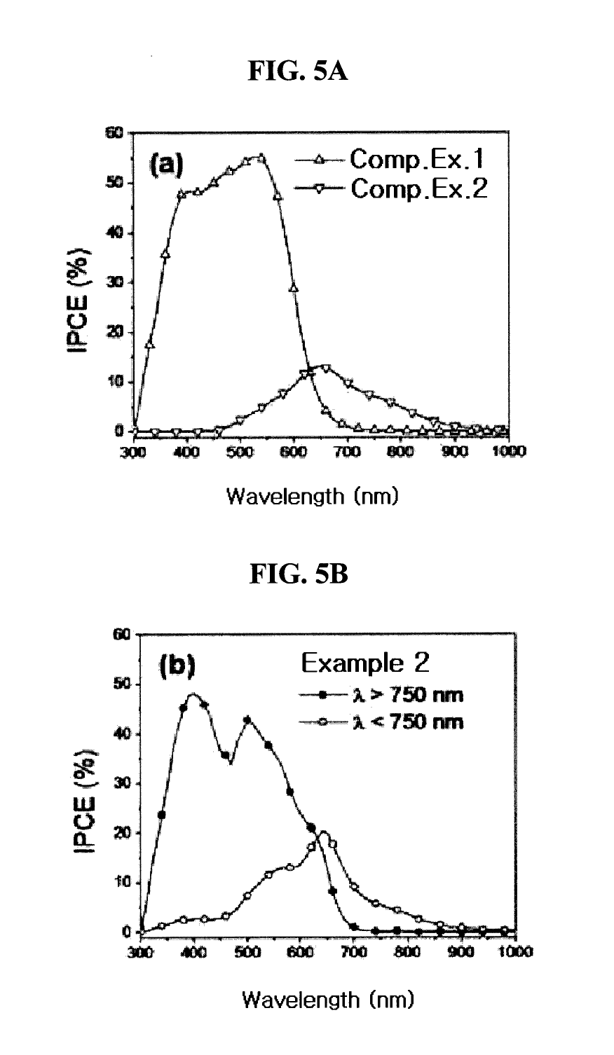

The results of measurement of IPCE of the solar cells of Example 2 and Comparative Examples 1 and 2 are shown in FIGS. 5A and 5B (FIG. 5A shows the IPCE of the single solar cells of Comparative Examples 1 and 2, and FIG. 5B shows the results obtained by radiating bias light onto the tandem solar cell of Example 2). As shown in these drawings, when bias light having a wavelength above 750 nm which corresponds to the wavelength range absorbed by the organic solar cell is applied, charges can be continuously generated and transferred by the organic solar cell, and current generated by the amorphous silicon solar cell is measured in the actual IPCE results. In contrast, when bias light having a wavelength below 750 nm is applied, current generated by the organic solar cell is measured. In the IPCE results, the amorphous silicon solar cell can absorb light ranging from 300 nm to 650 nm so that such light is converted into photocurrent. Because the light transmittance of the amorphous silicon solar cell increases from 500 nm, light that has passed through the amorphous silicon solar cell is absorbed by the organic solar cell in the wavelength range from 500 nm to 900 nm and is thus converted into photocurrent. In the case where the tandem solar cell is manufactured using these two kinds of solar cells, light over a wider range of wavelengths can be absorbed and thus converted into photocurrent.

What is claimed is:

1. A tandem solar cell comprising an amorphous silicon solar cell including a photoactive layer made of amorphous silicon; and an organic solar cell including a photoactive layer made of an organic material, which are stacked and electrically connected in series.

2. The tandem solar cell of claim 1, which has the structure that comprises a glass substrate, a transparent electrode layer, a p-type amorphous silicon layer, an i-type amorphous silicon layer, an n-type amorphous silicon layer, a hole transporting layer, an organic photoactive layer, and a metal electrode layer which are sequentially stacked.

3. The tandem solar cell of claim 2, which further include an electron transporting layer placed between the organic photoactive layer and the metal electrode layer.

4. The tandem solar cell of claim 2, which further include a metal recombination layer placed between the n-type amorphous silicon layer and the hole transporting layer.

5. The tandem solar cell of claim 2, wherein the hole transporting layer is made of one or more materials selected from the group consisting of titanium (Ti) oxide, zirconium (Zr) oxide, strontium (Sr) oxide, zinc (Zn) oxide, indium (In) oxide, lanthanum (La) oxide, vanadium (V) oxide, molybdenum (Mo) oxide, tungsten (W) oxide, tin (Sn) oxide, niobium (Nb) oxide, magnesium (Mg) oxide, aluminum (Al) oxide, yttrium (Y) oxide, scandium (Sc) oxide, samarium (Sm) oxide, gallium (Ga) oxide, strontium-titanium (Sr—Ti) oxide, lithium fluoride (LiF), poly(3,4-ethylenedioxythiophene):poly(styrenesulfonate) (PEDOT:PSS), polyaniline, and polypyrrole.

6. The tandem solar cell of claim 3, wherein the electron transporting layer is made of one or more materials selected from the group consisting of titanium (Ti) oxide, zirconium (Zr) oxide, strontium (Sr) oxide, zinc (Zn) oxide, indium (In) oxide, lanthanum (La) oxide, vanadium (V) oxide, molybdenum (Mo) oxide, tungsten (W) oxide, tin (Sn) oxide, niobium (Nb) oxide, magnesium (Mg) oxide, aluminum (Al) oxide, yttrium (Y) oxide, scandium (Sc) oxide, samarium (Sm) oxide, gallium (Ga) oxide, strontium-titanium (Sr—Ti) oxide, lithium fluoride (LiF), poly(3,4-ethylenedioxythiophene):poly(styrenesulfonate) (PEDOT:PSS), polyaniline, and polypyrrole.

7. The tandem solar cell of claim 4, wherein the metal recombination layer is made of one or more materials selected from the group consisting of gold (Au), silver (Ag), nickel (Ni), aluminum (Al), titanium (Ti), platinum (Pt), palladium (Pd) and copper (Cu).
